(19) United States
(12) Patent Application Publication
(10) Pub. No.: US 2024/0423073 A1
(43) Pub. Date: Dec. 19, 2024

(54) DISPLAY DEVICE

(71) Applicant: Samsung Display Co., LTD., Yongin-si (KR)

(72) Inventors: JAEHO YOU, Yongin-si (KR); YOUNGCHAN KIM, Yongin-si (KR)

(73) Assignee: Samsung Display Co., LTD., Yongin-si (KR)

(21) Appl. No.: 18/746,508

(22) Filed: Jun. 18, 2024

(30) Foreign Application Priority Data
Jun. 19, 2023 (KR) 10-2023-0078092

(51) Int. Cl. H10K 59/80

(52) U.S. Cl. CPC H10K 59/879

(57) ABSTRACT

A display device includes a display panel including a plurality of sub-pixel areas, a functional layer disposed on a surface of the display panel and including: a first protective layer, a refractive layer disposed on the first protective layer and including a plurality of first patterns, a second protective layer disposed on the refractive layer, a diffractive layer disposed on the second protective layer and including a plurality of second patterns spaced apart from each other at an interval, and a lens member disposed on a side of the functional layer and including a meta lens.

### CROSS-REFERENCE TO RELATED APPLICATION(S)

This application claims priority to and benefits of Korean Patent Application No. 10-2023-0078092 under 35 U.S.C. § 119, filed on Jun. 19, 2023, in the Korean Intellectual Property Office (KIPO), the entire contents of which are incorporated herein by reference.

### BACKGROUND

### 1. Technical Field

Embodiments provide a display device that provides information.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Recently, a head mounted display (“HMD”) including such a display device has been developed. The head mounted display is a glasses-type monitor device of virtual reality (“VR”) or augmented reality (“AR”) that is worn in the form of glasses, a helmet, or the like and focuses on a distance near the user's eyes. The head mounted display may provide an image displayed on a display device to the user's eyes through a lens.

### SUMMARY

Embodiments provide a display device with improved luminous efficiency.

A display device according to embodiments of the disclosure may include a display panel including a plurality of sub-pixel areas, a functional layer disposed on a surface of the display panel and including: a first protective layer, a refractive layer disposed on the first protective layer and including a plurality of first patterns, a second protective layer disposed on the refractive layer, and a diffractive layer disposed on the second protective layer and including a plurality of second patterns spaced apart from each other at an interval, and a lens member disposed on a side of the functional layer and including a meta lens.

In an embodiment, the functional layer may be disposed between the display panel and the lens member.

In an embodiment, the functional layer may directly contact the display panel.

In an embodiment, each of the plurality of first patterns may extend in a first direction, and the plurality of first patterns may be arranged in a second direction perpendicular to the first direction.

In an embodiment, the plurality of first patterns may be arranged in a first direction and a second perpendicular to the first direction.

In an embodiment, each of the plurality of first patterns may include a prism having an asymmetrical or symmetrical cross-sectional shape.

In an embodiment, the plurality of first patterns may include lenticular lenses.

In an embodiment, an angle between the second protective layer and each of the plurality of second patterns may be a right angle.

In an embodiment, each of the plurality of second patterns may be inclined at an angle.

In an embodiment, the display device may further include a third protective layer disposed on the diffraction layer and covering the diffraction layer.

In an embodiment, a refractive index of the diffraction layer and a refractive index of the third protective layer may be different.

In an embodiment, the second protective layer may cover the refractive layer, and the diffractive layer may be directly disposed on the second protective layer.

In an embodiment, the functional layer may be spaced apart from the display panel.

In an embodiment, the functional layer may include a first functional layer including the first protective layer and the refractive layer and a second functional layer including the second protective layer and the diffraction layer. The first functional layer may directly contact the display panel, and the second functional layer may be spaced apart from the first functional layer.

In an embodiment, the lens member may include a base substrate and a plurality of nanostructures disposed on the base substrate.

A display device according to embodiments of the disclosure may include a display panel including a silicon substrate including a plurality of sub-pixel areas, a driving circuit layer disposed on the silicon substrate, and an emission layer disposed in the plurality of sub-pixel areas on the driving circuit layer, a functional layer disposed on a surface of the display panel and including a first protective layer, a refractive layer disposed on the first protective layer and including a plurality of first patterns, a second protective layer disposed on the refractive layer, and a diffractive layer disposed on the second protective layer and including a plurality of second patterns spaced apart from each other at an interval, and a lens member disposed on a side of the functional layer and including a meta lens.

In an embodiment, the functional layer may be disposed between the display panel and the lens member.

In an embodiment, each of the plurality of second patterns may be inclined at an angle.

In an embodiment, the functional layer may be spaced apart from the display panel.

In an embodiment, the functional layer may include a first functional layer including the first protective layer and the refractive layer and a second functional layer including the second protective layer and the diffraction layer. The first functional layer may directly contact the display panel, and the second functional layer may be spaced apart from the first functional layer.

A display device according to an embodiment of the disclosure may include a functional layer disposed on a side of the display panel and a lens member disposed on a side of the functional layer and including a meta lens. The functional layer may include a refractive layer including a plurality of first patterns and a diffractive layer disposed on the refractive layer and including a plurality of second patterns. The functional layer may directly contact the display panel, or at least a part of the functional layer may be spaced apart from the display panel.

Accordingly, as the display device includes the functional layer, an optical distance between the display module including the display panel and the functional layer, and the lens member may be relatively reduced compared to a display device without the functional layer. As the display device includes the lens member including a meta lens, a thickness of the lens member may be relatively reduced compared to using a convex lens (or Fresnel lens). An overall thickness of the display device may be relatively reduced, and a luminous efficiency of the display device can be improved.

### BRIEF DESCRIPTION OF THE DRAWINGS

Illustrative, non-limiting embodiments will be more clearly understood from the following detailed description in conjunction with the accompanying drawings.

FIGS. 1A and 1B are perspective views of a display device according to an embodiment of the disclosure.

FIG. 2 is a side view of a display module accommodating portion of the display device of FIGS. 1A and 1B.

FIG. 3 is a plan view of a display module of FIG. 2.

FIG. 4 is a schematic cross-sectional view taken along line I-I′ of FIG. 3.

FIG. 5 is a plan view of a refractive layer of FIG. 4 according to an embodiment of the disclosure.

FIG. 6 is a plan view of a refractive layer of FIG. 4 according to an embodiment of the disclosure.

FIG. 7 is a schematic cross-sectional view illustrating a shape of first patterns included in the refractive layer of FIG. 4 according to an embodiment of the disclosure.

FIG. 8 is a schematic cross-sectional view illustrating a shape of first patterns included in the refractive layer of FIG. 4 according to an embodiment of the disclosure.

FIG. 9 is a schematic cross-sectional view illustrating the diffraction layer of FIG. 4 according to an embodiment of the disclosure.

FIG. 10 is a schematic cross-sectional view illustrating a display panel and a functional layer according to another embodiment of the disclosure.

FIG. 11 is a schematic cross-sectional view illustrating a display panel and a functional layer according to still another embodiment of the disclosure.

FIG. 12 is a schematic cross-sectional view illustrating a display panel and a functional layer according to still another embodiment of the disclosure.

FIG. 13 is a graph for explaining a relative luminance according to an emission angle of a display module according to comparative embodiment and embodiment.

### DETAILED DESCRIPTION OF THE EMBODIMENTS

Hereinafter, a display device according to embodiments of the disclosure will be explained in detail with reference to the accompanying drawings. The same reference numerals are used for the same components in the drawings, and redundant descriptions of the same components will be omitted.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

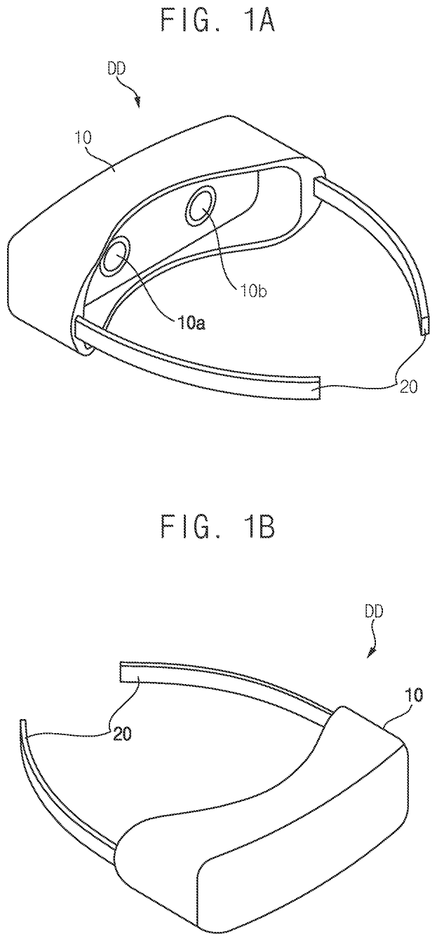

FIGS. 1A and 1B are perspective views of a display device according to an embodiment of the disclosure.

Referring to FIGS. 1A and 1B, the display device DD according to an embodiment of the disclosure may include a display module accommodating portion 10, a first eyepiece 10a, a second eyepiece 10b, and glasses frame legs 20.

For example, the display device DD according to an embodiment of the disclosure may be implemented as a head mounted display. However, the disclosure is not limited thereto, and the display device DD may be implemented as various wearable displays. Hereinafter, a head mounted display will be described as an embodiment of the display device DD.

Inside the display module accommodating portion 10, a display module for displaying an image and an optical member for providing the image displayed on the display module to the first and second eyepieces 10a and 10b may be disposed. For example, the display device DD may further include a display module and an optical member disposed inside the display module accommodating portion 10. A detailed description of the display module and the optical member will be described below.

The first and second eyepieces 10a and 10b may be disposed on a side of the display module accommodating portion 10. For example, the first and second eyepieces 10a and 10b may be disposed on a lower surface of the display module accommodating portion 10. For example, the first eyepiece 10a may be a left eye lens where the user's left eye is located, and the second eyepiece 10b may be a right eye lens where the user's right eye is located. The user may view the image displayed by the display module of the display module accommodating portion 10 through the first and second eyepieces 10a and 10b.

For example, each of the first and second eyepieces 10a and 10b may be a convex lens or a Fresnel lens. However, the disclosure is not limited thereto.

The display device DD may provide an image displayed on the display module of the display module accommodating portion 10 to the user through the first and second eyepieces 10a and 10b. As a result, the display device DD may provide the user with a virtual image displayed by the display module disposed inside the display module accommodating portion 10. For example, the display device DD may implement virtual reality (“VR”).

The glasses frame legs 20 may be configured so that the user can readily put them on or take them off. However, the disclosure is not limited thereto, and the display device DD may include a head mounting band that can be mounted on the head instead of the glasses frame legs 20.

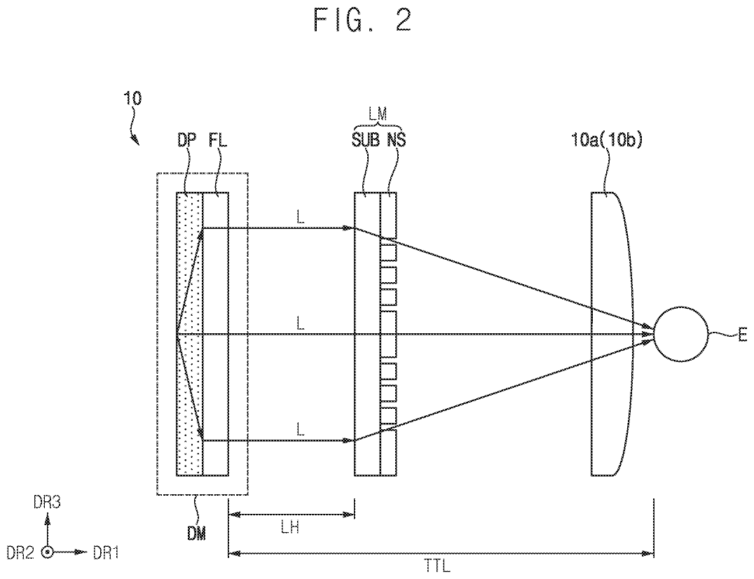

FIG. 2 is a side view of a display module accommodating portion of the display device of FIGS. 1A and 1B. For example, FIG. 2 shows components disposed inside the display module accommodating portion 10 for providing images to the first and second eyepieces 10a and 10b of the display device DD of FIGS. 1A and 1B.

Referring to FIGS. 1A, 1B, and 2, the display device DD according to an embodiment of the disclosure may include a display panel DP, a functional layer FL, and a lens member LM disposed inside the display accommodating portion 10.

The display panel DP may form a display module DM. For example, the display module DM may include the display panel DP, a driver, and a circuit board.

The driver may include a gate driver, an emission driver, a power supply voltage generator, a timing controller, and the like. The display panel DP may emit light based on a signal received from the driver. The circuit board may be electrically connected to multiple pads disposed in a non-display area of the display panel DP. For example, the circuit board may include a flexible printed circuit board (“FPCB”), a printed circuit board (“PCB”), a flexible flat cable (“FFC”), or the like.

The functional layer FL may be disposed on a side of the display panel DP. For example, the functional layer FL may be disposed between the display panel DP and the lens member LM. The functional layer FL may convert a wide emission distribution of the display panel DP into a narrow emission distribution. For example, a light L emitted from the display panel DP and passing through the functional layer FL may be vertically incident on the lens member LM. A detailed description of the components of the functional layer FL will be described below.

In an embodiment, the functional layer FL may contact (e.g., directly contact) the display panel DP. For example, the functional layer FL may not be spaced apart from the display panel DP, and the functional layer FL may be included in the display module DM. For example, the display panel DP may configure the display module DM together with the functional layer FL.

The lens member LM may be disposed between the functional layer FL and the eyepieces 10a and 10b. For example, the lens member LM may be arranged to be spaced apart from the display panel DP and the functional layer FL in the first direction DR1.

In an embodiment, the lens member LM may include a meta lens. The meta lens may function as a convex lens or a condensing lens. The light incident from the functional layer FL may pass through the lens member LM, be transmitted to the user's eye E, and form an image in the user's eye E.

For example, the meta lens may include amorphous silicon, polycrystalline silicon, single crystalline silicon, or the like. These can be used alone or in combination with each other. For example, the meta lens may include a conductive material. However, the disclosure is not limited thereto, and the meta lens may include a material other than the materials described above.

In an embodiment, in case that the lens member LM includes the meta lens, the lens member LM may include a base substrate SUB and multiple nanostructures NS disposed on the base substrate SUB. For example, the size of the nanostructures NS may be not constant and may have different sizes depending on the location.

As the display device DD includes the functional layer FL, an optical distance LH between the display module DM and the lens member LM may be relatively reduced compared to a display device without the functional layer FL. The optical distance LH may be a distance between the display module DM and the lens member LM. For example, the optical distance LH may be a distance between the functional layer FL and the lens member LM. For example, the optical distance LH may be less than about 10 mm, and a distance (total track length, TTL) between the display module DM and the user's eyes E may be reduced.

As the display device DD includes the lens member LM including the meta lens, a thickness of the lens member LM may be relatively reduced compared to using a convex lens or a Fresnel lens. For example, the thickness of the lens member LM may be less than or equal to about 1 mm, and the distance TTL between the display module DM and the user's eyes E may be reduced.

As described above, the distance TTL may be defined as the distance between the display module DM and the user's eyes E. For example, the distance TTL may be defined as the distance between the functional layer FL and the user's eyes E.

As a result, as the display device DD includes the functional layer FL and the lens member LM including the meta lens, an overall thickness of the display device DD may be relatively reduced, and the luminous efficiency of the display device DD may be improved.

As the above components are disposed inside the display module accommodating portion 10, images may be provided to the user through the first and second eyepieces 10a and 10b.

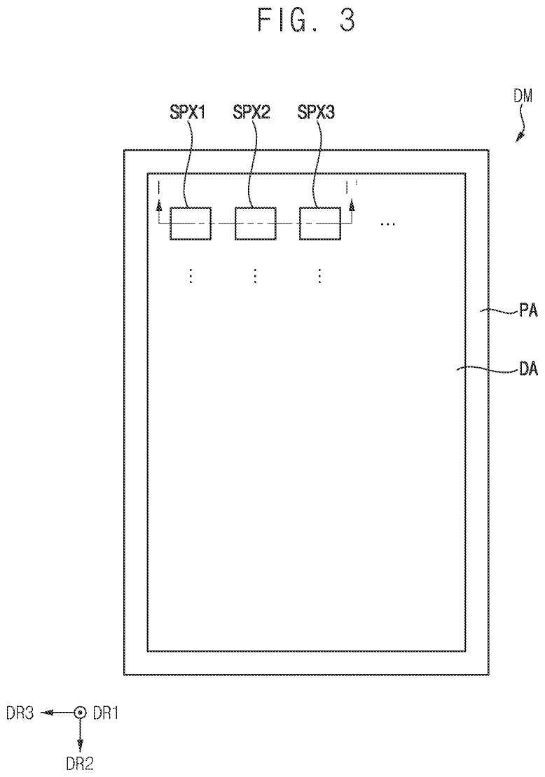

FIG. 3 is a plan view of a display module of FIG. 2.

Referring to FIG. 3, the display module DM may include a display area DA and a peripheral area PA. The display area DA may be an area that can display an image by generating light or adjusting the transmittance of light provided from an external light source. The peripheral area PA may be an area that does not display images. The peripheral area PA may be located adjacent to the display area DA. For example, the peripheral area PA may entirely surround the display area DA.

The display area DA may include multiple sub-pixel areas. The sub-pixel areas may be arranged in a matrix form along the second direction DR2 and the third direction DR3 intersecting the second direction DR2. For example, the sub-pixel areas may include a first sub-pixel area SPX1, a second sub-pixel area SPX2, and a third sub-pixel area SPX3. The second direction DR2 and the third direction DR3 may define a plane, and the first direction DR1 may be perpendicular to the plane.

Each of the first sub-pixel area SPX1, the second sub-pixel area SPX2, and the third sub-pixel area SPX3 may be an area where light emitted from an emission element is emitted to the outside of the display module DM. For example, the first sub-pixel area SPX1 may emit first light, the second sub-pixel area SPX2 may emit second light, and the third sub-pixel area SPX3 may emit third light. In an embodiment, the first light may be red light, the second light may be green light, and the third light may be blue light. However, the disclosure is not limited thereto. For example, the first, second, and third pixel areas SPX1, SPX2, and SPX3 may emit yellow, cyan, and magenta lights, respectively.

The first, second, and third sub-pixel areas SPX1, SPX2, and SPX3 may emit light of four or more colors. For example, the first, second, and third sub-pixel areas SPX1, SPX2, and SPX3 may emit at least one of yellow, cyan, and magenta lights in addition to red, green, and blue lights. The first, second, and third sub-pixel areas SPX1, SPX2, and SPX3 may emit white light.

Each of the first sub-pixel area SPX1, the second sub-pixel area SPX2, and the third sub-pixel area SPX3 may have a triangular shape, a tetragon shape, a circular shape, a track-shaped shape, an oval shape, or the like in a plan view. In an embodiment, each of the first sub-pixel area SPX1, the second sub-pixel area SPX2, and the third sub-pixel area SPX3 may have a tetragon shape in a plan view. However, the disclosure is not limited thereto, and each of the first sub-pixel area SPX1, the second sub-pixel area SPX2, and the third sub-pixel area SPX3 may have different shapes in a plan view.

The display module DM may have a rectangular shape in a plan view. However, the disclosure is not limited thereto, and the display module DM may have various shapes in a plan view (e.g., a rectangular shape with rounded corners or the like).

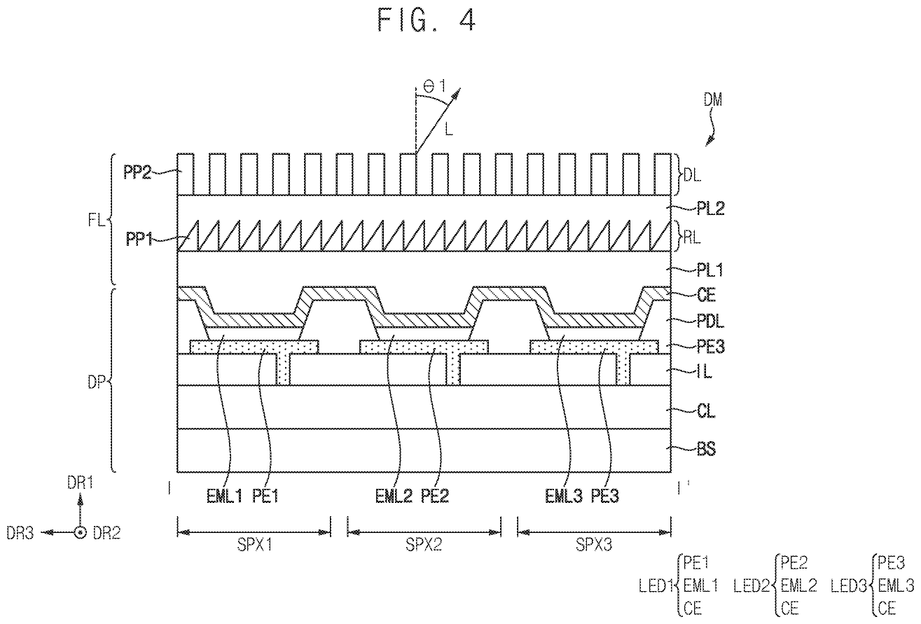

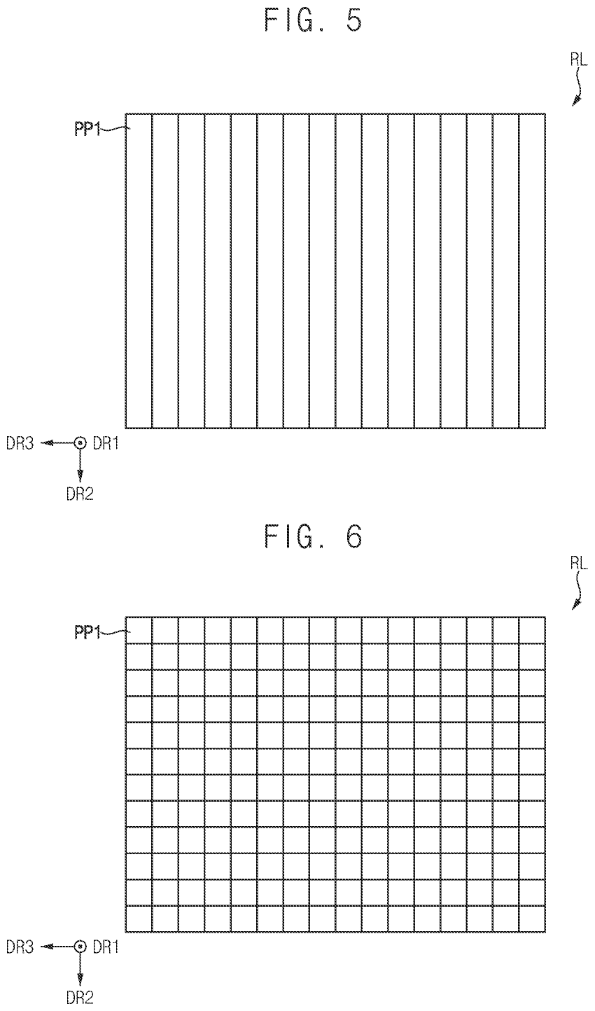

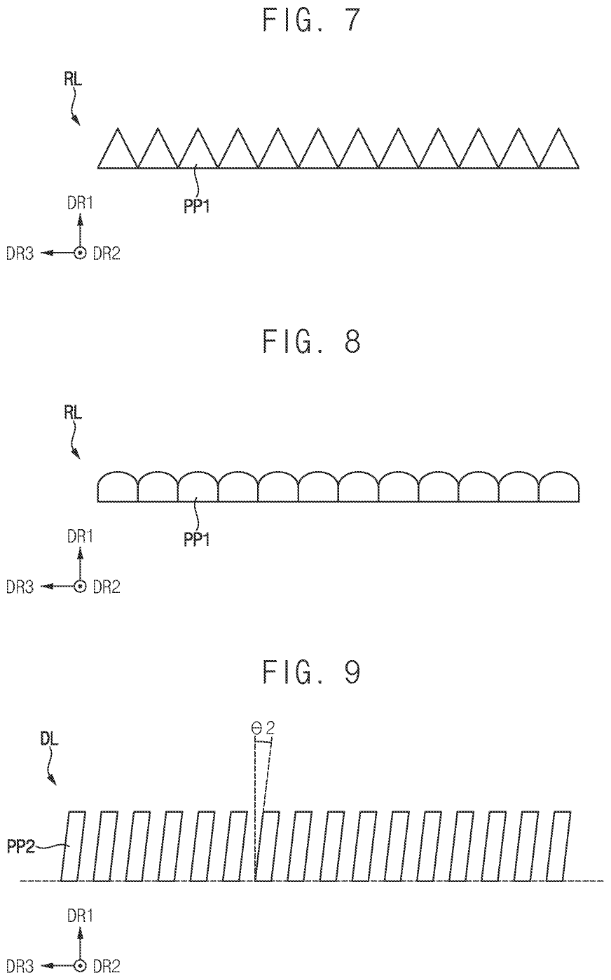

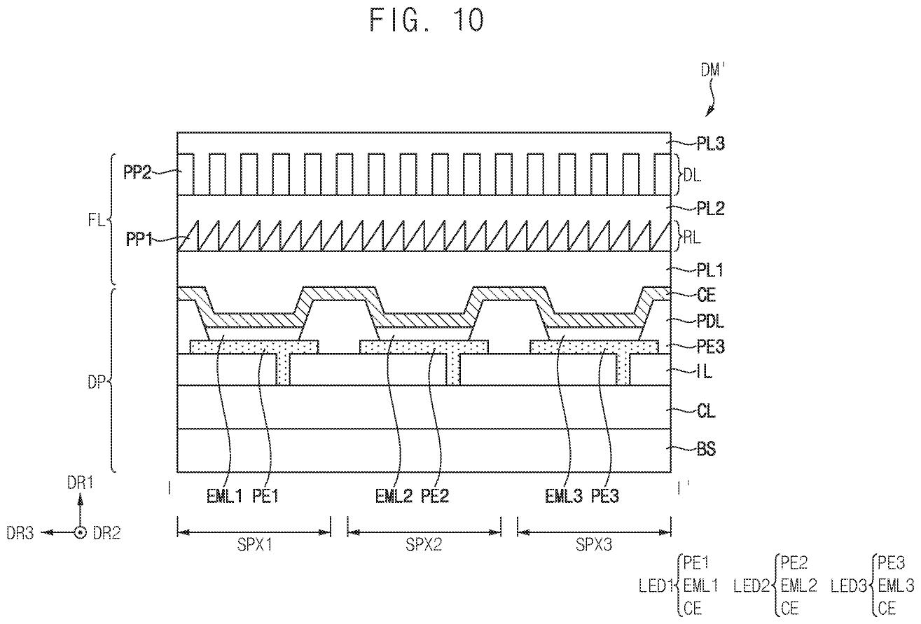

FIG. 4 is a schematic cross-sectional view taken along line I-I′ of FIG. 3. FIG. 5 is a plan view of a refractive layer of FIG. 4 according to an embodiment of the disclosure. FIG. 6 is a plan view of a refractive layer of FIG. 4 according to an embodiment of the disclosure. FIG. 7 is a schematic cross-sectional view illustrating a shape of first patterns included in the refractive layer of FIG. 4 according to an embodiment of the disclosure. FIG. 8 is a schematic cross-sectional view illustrating a shape of first patterns included in the refractive layer of FIG according to an embodiment of the disclosure. 4. FIG. 9 is a schematic cross-sectional view illustrating the diffraction layer of FIG. 4 according to an embodiment of the disclosure.

Referring to FIGS. 4, 5, 6, 7, and 8, the functional layer FL may be disposed on the display panel DP. As described above, the functional layer FL may contact (e.g., directly contact) the display panel DP. For example, the display panel DP and the functional layer FL may constitute the display module DM. In other words, the functional layer FL may be included in the display module DM.

The display panel DP may include a silicon substrate BS, a driving circuit layer CL, an insulating layer IL, first, second, and third emission elements LED1, LED2, and LED3, and a pixel defining layer PDL. The first emission element LED1 may include a first pixel electrode PE1, a first emission layer EML1, and a common electrode CE, the second emission element LED2 may include a second pixel electrode PE2, a second emission layer EML2, and a common electrode CE, and the third emission element LED3 may include a third pixel electrode PE3, a third emission layer EML3, and a common electrode CE.

As described above, the display module DM may include the display area DA including the first, second, and third sub-pixel areas SPX1, SPX2, and SPX3, and the peripheral area PA. As the display module DM includes the display area DA including the first, second, and third sub-pixel areas SPX1, SPX2, and SPX3 and the peripheral area PA, the display panel DP may also include the display area DA including the first, second, and third sub-pixel areas SPX1, SPX2, and SPX3, and the peripheral area PA.

The silicon substrate BS may be a support member for supporting other components of the display module DM. For example, the silicon substrate BS may be a silicon wafer substrate.

The driving circuit layer CL may be disposed on the silicon substrate BS. The driving circuit layer CL may include various driving elements, line, and the like for driving an emission element. For example, the driving circuit layer CL may include various components such as transistors, storage capacitors, gate lines, data lines, and the like.

The insulating layer IL may be disposed on the driving circuit layer CL. The insulating layer IL may prevent contact between the first, second, and third pixel electrodes PE1, PE2, and PE3 and the driving circuit layer CL. The insulating layer IL may include an organic material and/or an inorganic material. For example, the insulating layer IL may include an inorganic material such as silicon oxide (SiOₓ), silicon nitride (SiNₓ), silicon oxynitride (SiOₓN_{y}), or the like. These can be used alone or in combination with each other.

The first, second, and third pixel electrodes PE1, PE2, and PE3 may be disposed on the insulating layer IL. The first pixel electrode PE1 may overlap the first sub-pixel area SPX1, the second pixel electrode PE2 may overlap the second sub-pixel area SPX2, and the third pixel electrode PE3 may overlap the third sub-pixel area SPX3 in a plan view. Each of the first, second, and third pixel electrodes PE1, PE2, and PE3 may be connected to the driving circuit layer CL through a contact hole penetrating the insulating layer IL.

For example, each of the first, second, and third pixel electrodes PE1, PE2, and PE3 may include a metal, an alloy, a metal nitride, a conductive metal oxide, a transparent conductive material, or the like. These can be used alone or in combination with each other. For example, each of the first, second, and third pixel electrodes PE1, PE2, and PE3 may be an anode electrode. Each of the first, second, and third pixel electrodes PE1, PE2, and PE3 may be a reflective electrode or a transmissive electrode.

The pixel defining layer PDL may be disposed on the insulating layer IL and the first, second, and third pixel electrodes PE1, PE2, and PE3. An opening exposing at least a part of an upper surface of each of the first, second, and third pixel electrodes PE1, PE2, and PE3 may be defined in the pixel defining layer PDL. The pixel defining layer PDL may include an inorganic material and/or an organic material. For example, the pixel defining layer PDL may include an organic material such as a phenolic resin, a polyacrylate resin, a polyimide resin, a polyamide resin, a siloxane resin, an epoxy resin, or the like. These can be used alone or in combination with each other.

The first emission layer EML1 may be disposed on the first pixel electrode PE1, the second emission layer EML2 may be disposed on the second pixel electrode PE2, and the third emission layer EML3 may be disposed on the third pixel electrode PE3. For example, the first emission layer EML1 may overlap the first sub-pixel area SPX1, the second emission layer EML2 may overlap the second sub-pixel area SPX2, and the third emission layer EML3 may overlap the third sub-pixel area SPX3 in a plan view.

Each of the first, second, and third emission layers EML1, EML2, and EML3 may include an emission material that emits light of a color. For example, the first emission layer EML1 may include an emission material that emits red light, the second emission layer EML2 may include an emission material that emits green light, and the third emission layer EML3 may include an emission material that emits blue light. Functional layers (e.g., a hole injection layer, a hole transport layer, an electron injection layer, an electron transport layer, or the like) may be disposed under and/or on the first, second, and third emission layers EML1, EML2, and EML3. The functional layers may continuously extend across the first, second, and third sub-pixel areas SPX1, SPX2, and SPX3.

For example, each of the first, second, and third emission layers EML1, EML2, and EML3 may include one emission layer. For example, each of the first, second, and third emission layers EML1, EML2, and EML3 may include multiple emission layers sequentially stacked along a thickness direction (i.e., the first direction DR1).

However, the disclosure is not limited thereto, and the first, second, and third emission layers EML1, EML2, and EML3 may be formed integrally to form one emission layer that emits white light. The emission layer may continuously extend across the first, second, and third sub-pixel areas SPX1, SPX2, and SPX3, and the display module DM may further include a color filter disposed on the display panel DP.

The common electrode CE may be disposed on the first, second, and third emission layers EML1, EML2, and EML3. The common electrode CE may be disposed on an entire area of the display area DA. For example, the common electrode CE may include a metal, an alloy, a metal nitride, a conductive metal oxide, a transparent conductive material, or the like. These can be used alone or in combination with each other. For example, the common electrode CE may be a cathode electrode. The common electrode CE may be a transmissive (or semi-transmissive) or reflective electrode.

Accordingly, the first pixel electrode PE1, the first emission layer EML1, and the common electrode CE may constitute the first emission element LED1 in the first sub-pixel area SPX1, the second pixel electrode PE2, the second emission layer EML2, and the common electrode CE may constitute the second emission element LED2 in the second sub-pixel area SPX2, and the third pixel electrode PE3, the third emission layer EML3, and the common electrode CE may constitute the third emission element LED3 in the third sub-pixel area SPX3.

The functional layer FL may be disposed on the common electrode CE. In an embodiment, the functional layer FL may include a first protective layer PL1 disposed on the common electrode CE, a refractive layer RL disposed on the first protective layer PL1, a second protective layer PL2 disposed on the refractive layer RL, and a diffraction layer DL disposed on the second protective layer PL2.

The first protective layer PL1 may have a substantially flat upper surface. For example, the first protective layer PL1 may function as a planarization layer. For example, the first protective layer PL1 may include an inorganic material and/or an organic material.

In an embodiment, the refractive layer RL may include multiple first patterns PP1. The refractive layer RL may refract the path of light emitted from the first, second, and third emission layers EML1, EML2, and EML3 in a direction. For example, the refractive layer RL may include an inorganic material and/or an organic material.

For example, with respect to visible light, a refractive index of the refractive layer RL and a refractive index of the first protective layer PL1 may be the same.

In an embodiment, as shown in FIG. 5, each of the first patterns PP1 may extend in the second direction DR2, and the first patterns PP1 may be arranged in the third direction DR3.

In another embodiment, as shown in FIG. 6, the first patterns PP1 may be arranged in a matrix form in the second direction DR2 and the third direction DR3.

Each of the first patterns PP1 may have various cross-sectional shapes. In an embodiment, as shown in FIG. 4, each of the first patterns PP1 may include a prism having an asymmetrical cross-sectional shape. For example, each of the first patterns PP1 may have a triangular cross-sectional shape.

In another embodiment, as shown in FIG. 7, each of the first patterns PP1 may include a prism having a symmetrical cross-sectional shape. For example, each of the first patterns PP1 may have a triangular cross-sectional shape.

In another embodiment, as shown in FIG. 8, the first patterns PP1 may include a lenticular lens. For example, an upper surface of each of the first patterns PP1 may have a round cross-sectional shape.

The second protective layer PL2 may cover the refractive layer RL. The second protective layer PL2 may have a substantially flat upper surface. For example, the second protective layer PL2 may function as a planarization layer. For example, the second protective layer PL2 may include an inorganic material and/or an organic material.

The diffraction layer DL may be disposed on (e.g., directly disposed on) the second protective layer PL2. In an embodiment, the diffraction layer DL may include multiple second patterns PP2 spaced apart at an interval. For example, the second patterns PP2 may be spaced apart from each other in the third direction DR3. The diffraction layer DL may diffract light incident from the refraction layer RL so that the light is incident perpendicularly to a lens member (e.g., the lens member LM in FIG. 2). For example, the diffraction layer DL may include an inorganic material and/or an organic material.

For example, each of the second patterns PP2 may extend in the second direction DR2, and the first patterns PP1 may be arranged in the third direction DR3. For example, the second patterns PP2 may be arranged in a matrix form in the second direction DR2 and the third direction DR3.

For example, with respect to visible light, a refractive index of the diffraction layer DL and a refractive index of the second protective layer PL2 may be the same.

In an embodiment, for visible light, the refractive index of the diffraction layer DL and the refractive index of the refractive layer RL may be different. For example, the refractive index of the refractive layer RL may be greater than the refractive index of the diffractive layer DL. However, the disclosure is not limited thereto.

In an embodiment, as shown in FIG. 4, an angle between the second protective layer PL2 and each of the second patterns PP2 may be a right angle.

In another embodiment, as shown in FIG. 9, each of the second patterns PP2 may be inclined at an angle. For example, an angle θ2 formed by each of the second patterns PP2 with an imaginary line extending in the first direction DR1 may not be 0 degrees. In other words, the angle θ2 formed by each of the second patterns PP2 with the imaginary line may be in a range of about 0 degrees to about 90 degrees.

An angle θ1 (see FIG. 4) of the light L emitted from the display module DM may be defined as an emission angle. For example, the emission angle may be defined as the angle θ1 between an imaginary line extending in the first direction DR1 and the path of light L emitted from the display module DM. The display module DM may include both the display panel DP and the functional layer FL. In case that the functional layer FL is not included in the display module DM, the angle θ1 of the light L emitted from the display module DM and passing through the functional layer FL may be defined as an emission angle.

FIG. 10 is a schematic cross-sectional view illustrating a display panel and a functional layer according to another embodiment of the disclosure.

Hereinafter, descriptions that overlap with the display module DM described with reference to FIG. 4 will be omitted or simplified.

Referring to FIG. 10, the functional layer FL may be disposed on the display panel DP. The functional layer FL may contact (e.g., directly contact) the display panel DP. For example, the display panel DP and the functional layer FL may constitute a display module DM′. In other words, the functional layer FL may be included in the display module DM′. The display panel DP may include the silicon substrate BS, the driving circuit layer CL, the insulating layer IL, the first, second, and third emission elements LED1, LED2, and LED3, and the pixel defining layer PDL.

In an embodiment, the functional layer FL may further include a third protective layer PL3 disposed on the diffraction layer DL. The third protective layer PL3 may cover the diffraction layer DL. The third protective layer PL3 may have a substantially flat upper surface. For example, the third protective layer PL3 may function as a planarization layer. For example, the third protective layer PL3 may include an inorganic material and/or an organic material.

In an embodiment, with respect to visible light, a refractive index of the diffraction layer DL and a refractive index of the third protective layer PL3 may be different. For example, with respect to visible light, the refractive index of the diffraction layer DL may be greater than the refractive index of the third protective layer PL3.

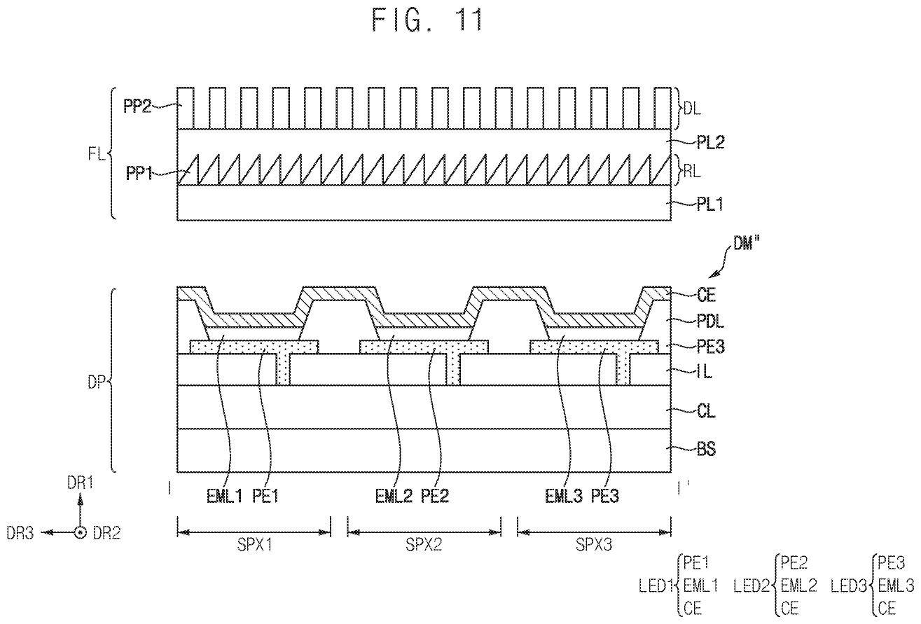

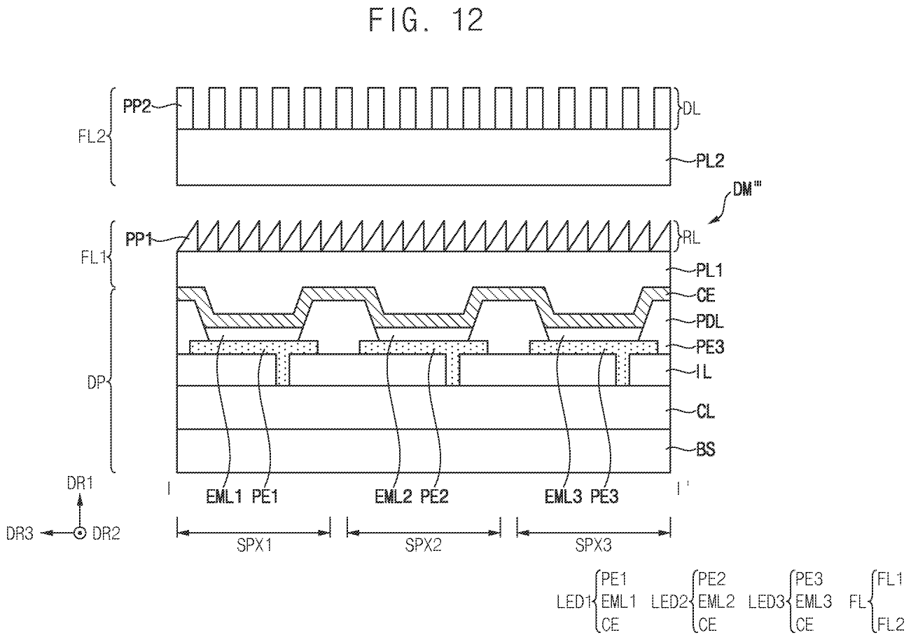

FIG. 11 is a schematic cross-sectional view illustrating a display panel and a functional layer according to still another embodiment of the disclosure.

Hereinafter, descriptions that overlap with the display module DM described with reference to FIG. 4 will be omitted or simplified.

Referring to FIG. 11, the functional layer FL may be disposed on the display panel DP. At least a part of the functional layer FL may be spaced apart from the display panel DP. In an embodiment, all of functional layer FL may be spaced apart from the display panel DP. For example, the functional layer FL may not be included in a display module DM″.

The display panel DP may include the silicon substrate BS, the driving circuit layer CL, the insulating layer IL, the first, second, and third emission elements LED1, LED2, and LED3, and the pixel defining layer PDL.

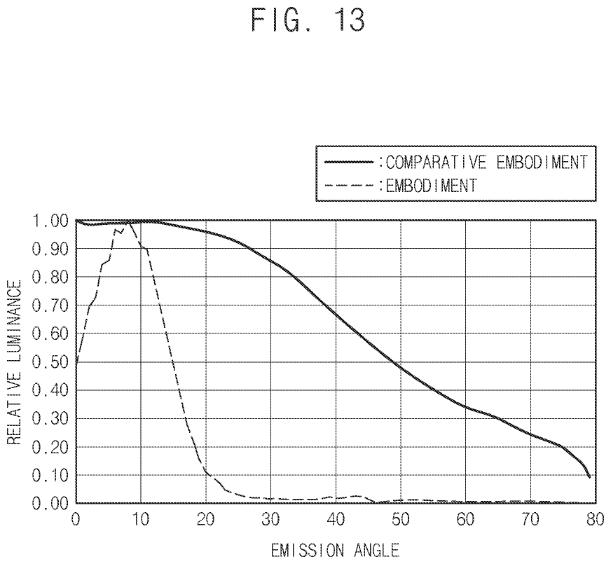

FIG. 12 is a schematic cross-sectional view illustrating a display panel and a functional layer according to still another embodiment of the disclosure.

Hereinafter, descriptions that overlap with the display module DM described with reference to FIG. 4 will be omitted or simplified.

Referring to FIG. 12, the functional layer FL may be disposed on the display panel DP. At least a part of the functional layer FL may be space apart from the display panel DP. In an embodiment, the functional layer FL may include a first functional layer FL1 including the first protective layer PL1 and the refractive layer RL, and a second functional layer FL2 including the second protective layer PL2 and the diffractive layer DL. The first functional layer FL1 may contact (e.g., directly contact) the display panel DP, and the second functional layer FL2 may be disposed on the first functional layer FL1, and spaced apart from the first functional layer FL1. For example, the first functional layer FL1 and the display panel DP may be included in a display module DM″, and the second functional layer FL2 may not be included in the display module DM″.

The display panel DP may include the silicon substrate BS, the driving circuit layer CL, the insulating layer IL, the first, second, and third emission elements LED1, LED2, and LED3, and the pixel defining layer PDL.

FIG. 13 is a graph for explaining a relative luminance according to an emission angle of a display module according to comparative embodiment and embodiment.

Referring to FIG. 13, a display module of the comparative embodiment does not include a functional layer including a refractive layer and a diffractive layer. A display module of the embodiment includes a functional layer including a refractive layer and a diffractive layer. The display module of the embodiment may correspond to the display module DM in FIG. 4.

Relative luminance according to the emission angle of light emitted from the display module was measured according to comparative embodiment and embodiment.

As a result, it can be confirmed that the light emitted from the display module of the comparative embodiment has a relatively wide emission light distribution. On the other hand, it can be confirmed that the light emitted from the display module of the embodiment has a relatively narrow emission light distribution. For example, in case that the light emitted from the display module has an emission angle greater than about 30 degrees (e.g., the angle θ1 in FIG. 4), the relative luminance of the light can be confirmed to be close to about 0.

The disclosure may be applied to various display devices. For example, the disclosure may be applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including a plurality of sub-pixel areas;
a functional layer disposed on a surface of the display panel and including:
a first protective layer;
a refractive layer disposed on the first protective layer and including a plurality of first patterns;
a second protective layer disposed on the refractive layer; and
a diffractive layer disposed on the second protective layer and including a plurality of second patterns spaced apart from each other at an interval; and
a lens member disposed on a side of the functional layer and including a meta lens.

2. The display device of claim 1, wherein the functional layer is disposed between the display panel and the lens member.

3. The display device of claim 1, wherein the functional layer directly contacts the display panel.

4. The display device of claim 1, wherein
each of the plurality of first patterns extends in a first direction, and
the plurality of first patterns are arranged in a second direction perpendicular to the first direction.

5. The display device of claim 1, wherein the plurality of first patterns are arranged in a first direction and a second perpendicular to the first direction.

6. The display device of claim 1, wherein each of the plurality of first patterns includes a prism having an asymmetrical or symmetrical cross-sectional shape.

7. The display device of claim 1, wherein the plurality of first patterns include lenticular lenses.

8. The display device of claim 1, wherein an angle between the second protective layer and each of the plurality of second patterns is a right angle.

9. The display device of claim 1, wherein each of the plurality of second patterns is inclined at an angle.

10. The display device of claim 1, further comprising:
a third protective layer disposed on the diffraction layer and covering the diffraction layer.

11. The display device of claim 10, wherein a refractive index of the diffraction layer and a refractive index of the third protective layer are different.

12. The display device of claim 1, wherein
the second protective layer covers the refractive layer, and
the diffractive layer is directly disposed on the second protective layer.

13. The display device of claim 1, wherein the functional layer is spaced apart from the display panel.

14. The display device of claim 1, wherein
the functional layer includes:
a first functional layer including the first protective layer and the refractive layer; and
a second functional layer including the second protective layer and the diffraction layer,
the first functional layer directly contacts the display panel, and the second functional layer is spaced apart from the first functional layer.

15. The display device of claim 1, wherein the lens member includes a base substrate and a plurality of nanostructures disposed on the base substrate.

16. A display device comprising:
a display panel including:
a silicon substrate including a plurality of sub-pixel areas;
a driving circuit layer disposed on the silicon substrate; and
an emission layer disposed in the plurality of sub-pixel areas on the driving circuit layer;
a functional layer disposed on a surface of the display panel and including:
a first protective layer;
a refractive layer disposed on the first protective layer and including a plurality of first patterns;
a second protective layer disposed on the refractive layer; and
a diffractive layer disposed on the second protective layer and including a plurality of second patterns spaced apart from each other at an interval; and
a lens member disposed on a side of the functional layer and including a meta lens.

17. The display device of claim 16, wherein the functional layer is disposed between the display panel and the lens member.

18. The display device of claim 16, wherein each of the plurality of second patterns is inclined at an angle.

19. The display device of claim 16, wherein the functional layer is spaced apart from the display panel.

20. The display device of claim 16, wherein
the functional layer includes:
a first functional layer including the first protective layer and the refractive layer, and
a second functional layer including the second protective layer and the diffraction layer,
the first functional layer directly contacts the display panel, and
the second functional layer is spaced apart from the first functional layer.
